(19) United States
(12) Patent Application Publication
(10) Pub. No.: US 2006/0003269 A1
(43) Pub. Date: Jan. 5, 2006

(54) Resist pattern forming method, substrate processing method, and device manufacturing method

(75) Inventors: Toshiki Ito, Kawasaki-shi (JP); Natsuhiko Mizutani, Tokyo (JP); Takako Yamaguchi, Kawasaki-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/168,422

(22) Filed: Jun. 29, 2005

(30) Foreign Application Priority Data
Jun. 30, 2004 (JP) 194821/2004(PAT)

(51) Int. Cl. G03F 7/00

(52) U.S. Cl. 430/323; 430/322

(57) ABSTRACT

Disclosed is a pattern forming method for forming a resist pattern on a substrate to be processed. The method includes a resist layer forming step for forming a resist layer on the substrate, an exposure step for exposing the resist layer with near-field light, and a developing step for developing the exposed resist layer, wherein the resist layer is made of a resist material having an Y value calculated from a sensitivity curve, not less than 1.6.

### FIELD OF THE INVENTION AND RELATED ART

This invention relates to a resist pattern forming method, a substrate processing method and a device manufacturing method. More particularly, the invention concerns technologies based on near-field optical lithography.

In the fields of various electronic devices such as semiconductor devices, for example, which need microprocessing procedures, because of requirements for further enlargement of device density and integration, the pattern size has to be miniaturized more and more. One of the semiconductor manufacturing processes which plays an important role for formation of an extraordinarily fine pattern is a photolithographic process.

The photolithographic process is currently carried out on the basis of reduction projection exposure. The resolution thereof is restricted by diffraction limits of light, and generally it is about one-third of the wavelength of a light source used. Hence, for finer microprocessing, the wavelength for exposure has been shortened such as, for example, by using an excimer laser as an exposure light source. As a result of this, microprocessing of about 100 nm order has currently been enabled.

Although the photolithography has been adapted to further miniaturization, the shortening of the wavelength of light sources have raised many problems such as bulkiness of apparatus, development of lenses usable in shortened wavelengths, cost of apparatus, cost of usable resist materials, and so on.

On the other hand, as another attempt to making finer patterns, a method using near-field light to perform microprocessing of a resolution less than the wavelength of light has been proposed. Such near-field optical lithography is free from the restriction due to the diffraction limits of light, and thus a spatial resolution of one-third or less of the light source wavelength is attainable.

As regards such near-field optical lithography, there are two methods, that is, a method in which a probe provided by an optical fiber having its free end sharp-pointed by wet etching is scanned (Japanese Laid-Open Patent Application, Publication No. 7-106229) and a method in which a photomask having a light blocking film with openings narrower than the light source wavelength is closely contacted to a resist and one-shot exposure is carried out (U.S. Pat. No. 6,171,730).

The near-field optical lithograph has another advantage that, if a mercury lamp or a semiconductor laser is used as an exposure light source, the exposure light source can be made very small and therefore the apparatus can be made very compact and yet the cost of the apparatus can be made lower.

In a resist pattern forming method wherein a resist pattern is formed on the basis of near-field optical lithography as described above, regarding the resist pattern to be produced, not only a high resolution being smaller than the wavelength of light but also a higher linewidth precision are being required.

FIG. 9 shows a light intensity distribution, obtained by theoretical calculation, around openings of a mask in near-field optical lithography of photomask one-shot exposure type. It is seen from the drawing that the light intensity is distributed with expansion about the photomask openings.

Thus, in order to assure that a resist pattern having high linewidth precision is produced on the basis of near-field optical lithography having such characteristic light intensity distribution, optimum resist materials must be chosen.

### SUMMARY OF THE INVENTION

It is accordingly an object of the present invention to provide an improved resist pattern forming method, an improved substrate processing method and/or an improved device manufacturing method, by which a resist pattern having higher linewidth precision can be produced.

In accordance with an aspect of the present invention, there is provided a method of forming a resist pattern on a substrate to be processed, said method comprising the steps of: forming a resist layer on the substrate; exposing the resist layer with near-field light; and developing the exposed resist layer; wherein the resist layer is made of a resist material having an Y value calculated from a sensitivity curve, not less than 1.6.

Briefly, in accordance with the present invention, a resist layer to be formed on a substrate to be processed is made of a resist material having an Y value, calculated from a sensitivity curve, not less than 1.6, and this ensures provision of a resist pattern having very high linewidth precision, in the near-field optical lithography.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIG. 1 is a schematic view of a general structure of an exposure apparatus into which a resist pattern forming method according to an embodiment of the present invention is incorporated.

FIGS. 2A and 2B are plane view and a sectional view, respectively, for explaining an exposure mask to be used in the exposure apparatus of FIG. 1.

FIG. 3 is a graph for explaining sensitivity curves and Y values of a chemical amplification type resist and a diazo-naphthoquinon Novolak type resist.

FIG. 4 is a graph for explaining sensitivity curves of virtual resist materials.

FIG. 5 is a graph, illustrating a light intensity distribution obtained by theoretic calculation.

FIG. 6 is a graph for explaining an example of a latent pattern of a resist determined by theoretical calculation with respect to an exposure amount 383 mJ/cm².

FIGS. 7A and 7B are graphs for explaining another example of a latent pattern of a resist determined by theoretical calculation with respect to an exposure amount 383 mJ/cm².

FIGS. 8A, 8B and 8C are graphs for explaining an example of a latent pattern of a resist determined by theoretical calculation with respect to an exposure amount 794 mJ/cm².

FIG. 9 is a graph for explaining a light intensity distribution obtained by theoretical calculation, around mask openings in conventional near-field optical lithography.

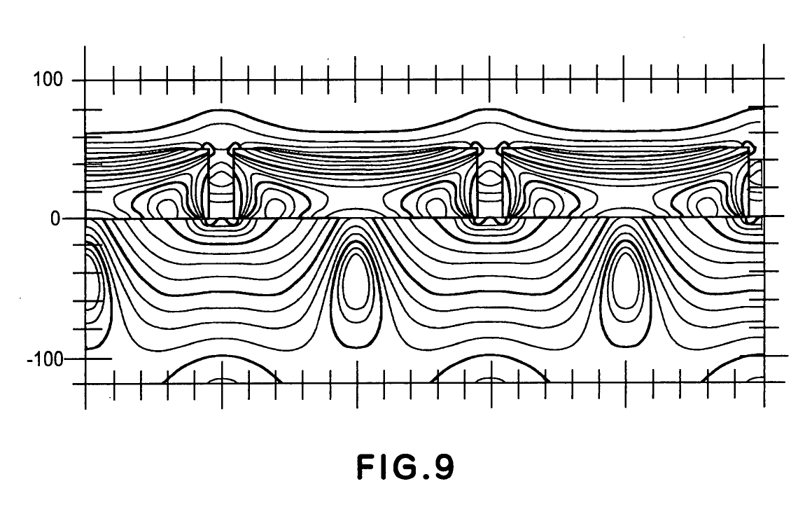

### DESCRIPTION OF THE PREFERRED EMBODIMENTS

Preferred embodiments of the present invention will now be described with reference to the attached drawings.

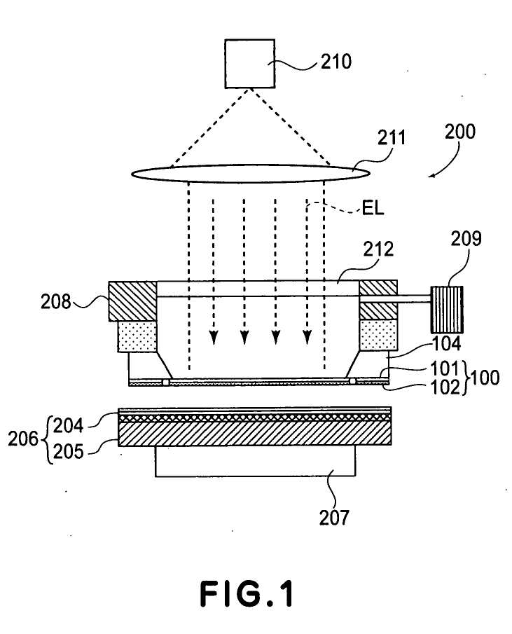

FIG. 1 is a schematic view of a general structure of an exposure apparatus into which a resist pattern forming method according to an embodiment of the present invention is incorporated. In FIG. 1, denoted at 200 is a near-field exposure apparatus that comprises a pressure adjusting container 208, an exposure light source 210, a stage 207, and a pressure adjusting device 209 for adjusting the pressure inside the pressure adjusting container 208.

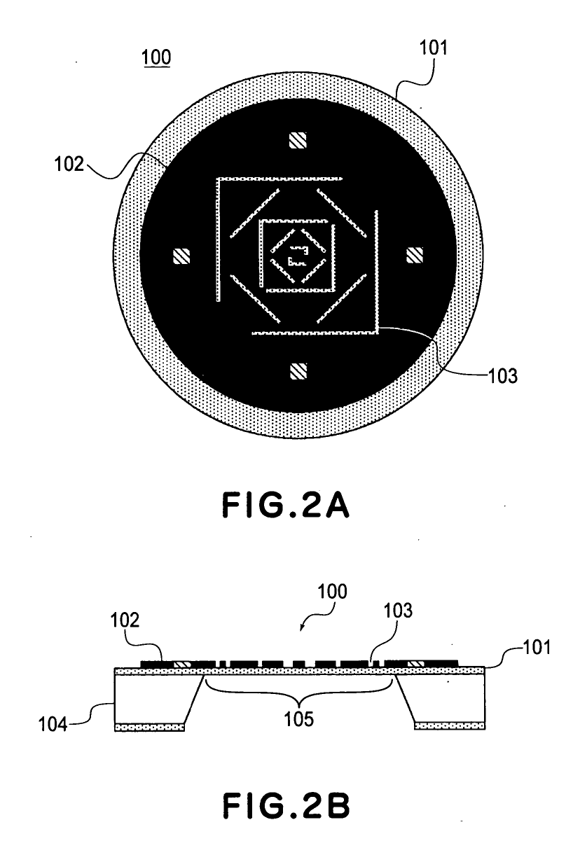

Denoted at 100 in FIG. 1 is an exposure mask which is attached to the bottom of the pressure adjusting container 208. As best seen in FIGS. 2A and 2B, this exposure mask 100 comprises a mask supporting member 104, a mask base material 101 and a light blocking film 102. The light blocking film 102 is formed to be held by the mask base material 101 which is a thin-film holding member made of an elastic (resilient) material. The light blocking film 102 has fine openings 103 formed in a desired pattern.

At least a central portion of the exposure mask 100, off the mask supporting member 104, provides an elastically deformable thin film portion 105. Hereinafter, the surface of the exposure mask 100 shown in FIG. 2A, that is, the surface on which the light blocking film 102 is provided, will be referred to as “front surface” and the surface on the other side will be referred to as “back surface”. The exposure mask 100 is attached to the bottom of the pressure adjusting container 208 through the mask supporting member 104.

Denoted at 206 in FIG. 1 is a workpiece to be exposed, being mounted on a stage 207 which is movable means that can be moved two dimensionally along the mask surface and also in a direction of a normal to the mask surface. The workpiece 206 to be exposed comprises a substrate 205 and a resist 204 formed on the surface of the substrate 205. The workpiece 206 is placed on the stage 207 and, after that, by moving the stage 207, relative positional alignment of the substrate 205 with the exposure mask 100 with respect to two-dimensional directions along the mask surface is achieved. Thereafter, the workpiece is moved in the direction of a normal to the mask surface.

Denoted at 211 in FIG. 1 is a collimator lens that functions to transform exposure light EL emitted from an exposure light source 210 into parallel light. The exposure light being transformed into parallel light by the collimator lens 211 passes through a glass window 212 formed on the top of the pressure adjusting container 208, and it enters the pressure adjusting container 208.

Next, an exposure method to be carried out in the near-field exposure apparatus 200 having a structure such as described above will be explained.

First of all, the exposure mask 100 is attached to the bottom of the pressure adjusting container 208, with its front surface being faced to the workpiece 206 to be exposed. Subsequently, the workpiece 206 is placed on the stage 207 and, by moving the stage 207, relative alignment of the workpiece with the exposure mask 100 with respect to the two-dimensional directions along the mask surface is carried out. Thereafter, the workpiece 206 is moved in the direction of a normal to the mask surface, until the distance therefrom to the exposure mask 100 becomes equal to a certain preset distance.

Subsequently, a gas is supplied into the pressure adjusting container 208 from the pressure adjusting means 209, and a pressure is applied to the exposure mask 100 from the back surface thereof to the front surface thereof. The pressure is applied to cause elastic deformation (flexure) of the exposure mask 100 (thin film portion 105 thereof) toward the workpiece side to bring the exposure mask 100 into contact (intimate contact) with the workpiece 206 so that the clearance between the surface of the exposure mask 100 and the surface of the resist 204 on the substrate 205 is kept equal to 100 nm or under, throughout the whole mask surface.

Subsequently, after the exposure mask 100 is brought into intimate contact with the workpiece 206, exposure light EL emitted from the exposure light source 210 and transformed into parallel light by the collimator lens 211 is projected into the pressure adjusting container 208 through the glass window 212, to illuminate the exposure mask 100 from its back surface. In response, near-field light leaks or escapes from the fine-opening pattern which is formed in the light blocking film 102 on the mask base material 101 of the exposure mask 100, such that, on the basis of the near-field light, exposure of the workpiece 206 is carried out.

Subsequently, after the exposure process such as described above is completed, the gas inside the pressure adjusting container 208 is discharged outwardly so that the same pressure as the outside pressure is produced inside the container. In response, the flexure of the exposure mask 100 is released, and thus the exposure mask 100 disengages from the workpiece 206. If there is any attraction force present between the exposure mask 100 and the workpiece 206, the exposure mask 100 may not disengage from the workpiece 206 even though the inside pressure of the pressure adjusting container is made equal to the outside pressure thereof. In such case, the pressure inside the pressure adjusting container may be made lower than the outside pressure to cause upward flexure of the exposure mask as viewed in the drawing to thereby strengthen the force of disengagement.

With the procedure described above, the exposure process is completed and a desired pattern can be transferred to the workpiece 206. In this embodiment, a pressure application method is used to apply a pressure to the exposure mask 100 to cause flexure of the same. In place of this, an electrostatic force may be provided to between the exposure mask 100 and the workpiece 206 to cause flexure of the exposure mask 100 toward the workpiece 206. Anyway, the present invention is not limited to a particular method in regard to producing mask flexure.

In this embodiment, the resist 204 formed on the surface of the substrate (to be processed) of the workpiece 206 is made of a resist material having an Y value, which can be determined from a sensitivity curve and which represents the magnitude of development contrast, being not less than 1.6, more preferably, not less than 2.5. By using such a resist 204, through the near-field optical lithography the formation of a resist pattern having very high linewidth precision is assured.

Measurement of the sensitivity curve as well as calculation of the Y value are carried out as follows.

For the sensitivity curve measurement, firs of all, a predetermined resist is applied onto a predetermined substrate, and it is prebaked. Here, the film thickness of the resist is set to obtain 160-200 nm thickness after the prebaking. The substrate to be used and the coating and prebaking methods will be described later.

Subsequently, a gray scale having an optical density step of 0.2 or less is placed on the resist layer, and then the resist is exposed by the whole-surface one-shot exposure process using propagating light as outputted from the same light source as used in the near-field optical lithography. Here, the gray scale to be used may be a synthetic silica linear step density filter available from Edmund Optics Japan, for example. The light source to be used in the near-field optical lithography will be explained later.

Subsequently, as required, heating (baking) is carried out under a predetermined condition after the exposure, and then the resist is cooled to a room temperature. After the exposure or after the post exposure bake, the resist is developed under a predetermined developing condition. The conditions for the post exposure bake and the development are the same as those to be set in the actual procedure for forming a pattern through the near-field optical lithography. The conditions and methods for the post exposure bake process and the development process will be described later.

Subsequently, the film thickness after the development at each step of the gray scale is measured, and the results are plotted along the axis of ordinate while a logarithm taking the bottom of the exposure amount as 10 is put on the axis of abscissa. For this film thickness measurement, a spectral ellipsometry, a contact type surface step gauge, an atomic force microscope, a scan type electron microscope, a transmission type electron microscope, etc., may be used. However, use of a spectral ellipsometry is particularly preferable.

The film thickness to be plotted here is a standardized film thickness while taking the film thickness of an unexposed portion after the development as 1. In the case of negative type resist, the film thickness may be standardized while taking the film thickness of a portion having been exposed with an exposure amount sufficiently larger than an optimum exposure amount best suited to the pattern formation as 1. A graph that can be provided in this manner is a sensitivity curve.

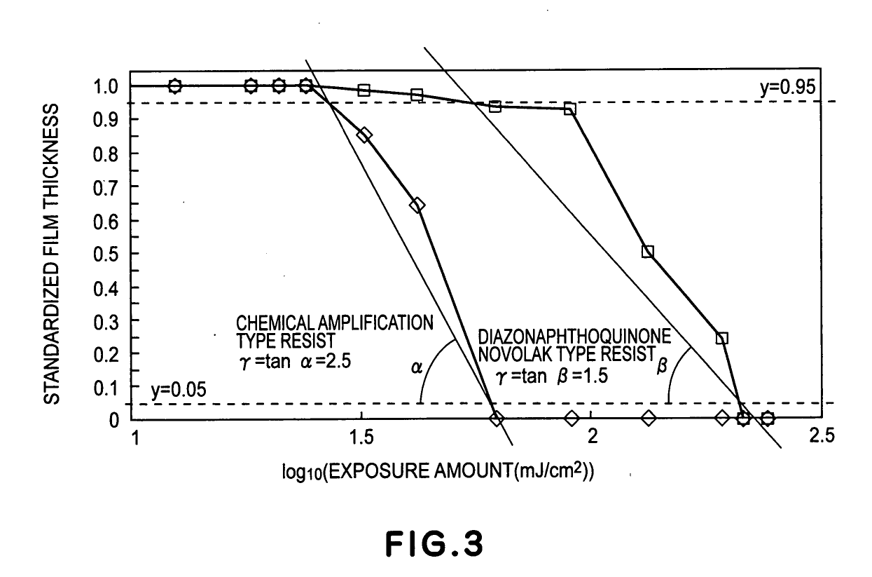

On the other hand, for calculation of the Y value from the thus obtainable sensitivity curve, respective points on the sensitivity curve shown in FIG. 3 (to be described later) are connected by straight lines and then the tilt of a straight line connecting two points, that is, the point of intersection between the sensitivity curve and a straight line y=0.05 and the point of intersection between the sensitivity curve and a straight line y=0.95, is detected. An absolute value of the tilt of the straight line thus detected is the Y value.

Hereinafter, the region having been exposed with an exposure amount with which the standardized film thickness becomes not less than 0 but not larger than 1 will be referred to as a “gray zone”. Since such gray zone is very sensitive even to a small change of developing condition, there is a possibility that the linewidth of the resist pattern after development disperses within the upper limit determined by the width of the gray zone. This means that the larger the Y value is (i.e., the smaller the gray zone is), the higher the linewidth precision is.

As a resist having large Y value, chemical amplification type resists may preferably be used. The chemical amplification type resists include a positive type resist that uses a deprotection reaction based on an optically latent acid catalyst of an alkali soluble group, being protected by an acid decomposing protective group, and a negative type resist that uses a condensation bridging reaction based on an optically latent acid catalyst of a phenol resin, such as Novolak resin or polyhydroxystyrene, with a bridging agent such as melamine compound or urea compound. Generally, there resist materials may have a higher development contrast than positive type resists of diazo-naphthoquinon Novolak type or negative type resists of optical cationic polymerization type, optical radical polymerization type, polyhydroxystyrene-bisazide type, cyclized-rubber-bisazide type, or polycinnamic acid vinyl type (“Survey of Latest Electronics Resists”, Toray Research Center Inc. Japan, 2003, or “Resist Material Handbook”, Realize Inc. Japan, 1996).

Next, an example where the Y values of a chemical amplification type resist and a diazo-naphthoquinon Novolak type resist were actually measured will be described.

In this measurement example, as a chemical amplification type resist, a positive type resist containing, as a major ingredient, polyhydroxystyrene having its phenolic hydroxyl group protected by acetal bond as well as an i-line sensitive photoacid generator, was used. On the other hand, as a diazo-naphthoquinon Novolak type resist, a positive type resist containing, as a main ingredient, diazo-naphthoquinon sulfonate compound and cresol-Novolak resin, was used.

In the measurement, first, these two resists were applied to silicon substrates, respectively, by using a spin coater and under the condition that the respective film thicknesses after the prebake became approximately equal to 190 nm. The prebake was carried out upon a hot plate at 90° C. for 90 seconds for the chemical amplification type resist, and at 100° C. for 90 seconds for the diazo-naphthoquinon Novolak resist.

Subsequently, a gray scale having an optical density step of 0.2 was placed on the resists, and the resists were exposed with i-line monochromatic light of an illuminance 6.73 mW/cm² obtained by putting an i-line interference filter to a mercury lamp light source, for 10 seconds, 50 seconds, and 500 seconds. Thereafter, post exposure bake was carried out only to the chemical amplification type resist, upon a hot plate and at 110° C. for 90 seconds.

Subsequently, the resists were developed for 10 seconds by using a 2.38% aqueous solution of tetramethyl ammonium hydroxide, and then they were rinsed by pure water for 20 seconds. Then, the film thicknesses in zones corresponding to respective exposure amounts after development were measured by using a spectral ellipsometry. FIG. 3 shows sensitivity curves obtained by plotting the thus measured values.

Then, the Y values of the resists were calculated in the manner described above. The result were that the Y value of the chemical amplification type resist was 2.5 while that of the diazo-naphthoquinon Novolak type resist was 1.5. Thus, it was confirmed that the chemical amplification type resist showed a higher development contrast.

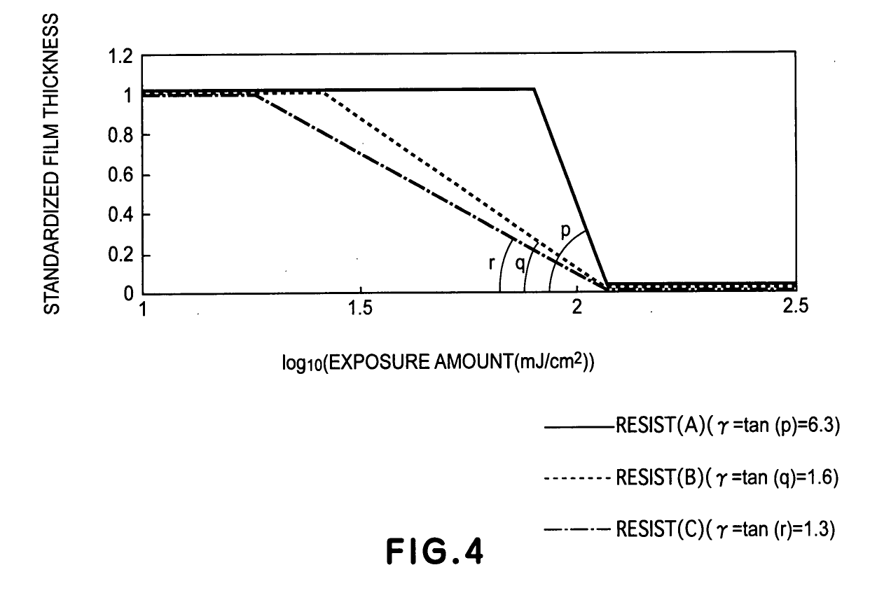

Next, referring to FIG. 4, the present invention will be described specifically with reference to three types of virtual positive type resists having different Y values but having the same smallest exposure amount 114 mJ/cm², making the standardized film thickness after development equal to zero.

Using a program “Max-1” (C. Hafner, Max-1, A Visual Electromagnetics Platform, Wiley, Chichester, UK, 1998) according to GMT (Generalized Multipole Technique), the light intensity distribution formed around the small openings was simulated. Here, “GMT” is one analysis method based on Maxwell's equation, and it is a method that describes scattering waves while placing a multipole as a virtual source.

In the simulation, calculations were made taking SiN as the mask base material and Cr as the light blocking film, while setting the opening width 20 nm, the pattern pitch 200 nm, and the incident wavelength 436 nm.

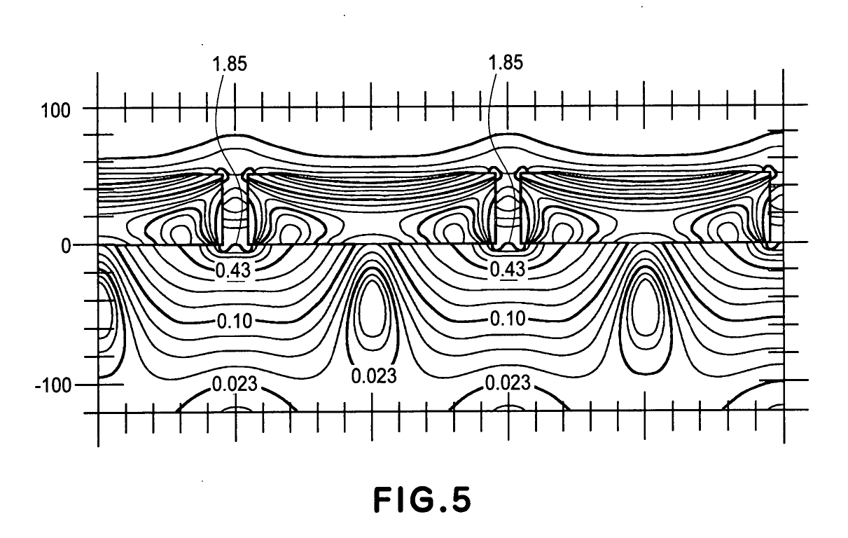

FIG. 5 shows the results. Numerical values in FIG. 5 represent relative light intensities when the incident light intensity is taken as 1.0. The isointensity lines in the drawing have a ratio of geometrical series of 1.44, and, for every four lines, one line is being drawn thick. More specifically, the relative light intensities are, from the thick line just under the opening and with reference to the incident light intensity of 1, 1.85, 0.43, 0.10 and 0.023.

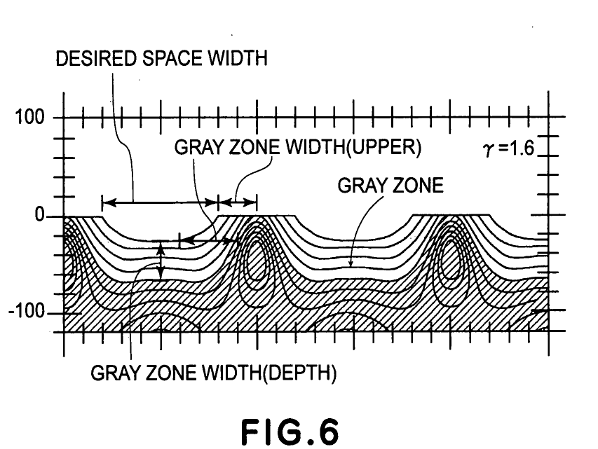

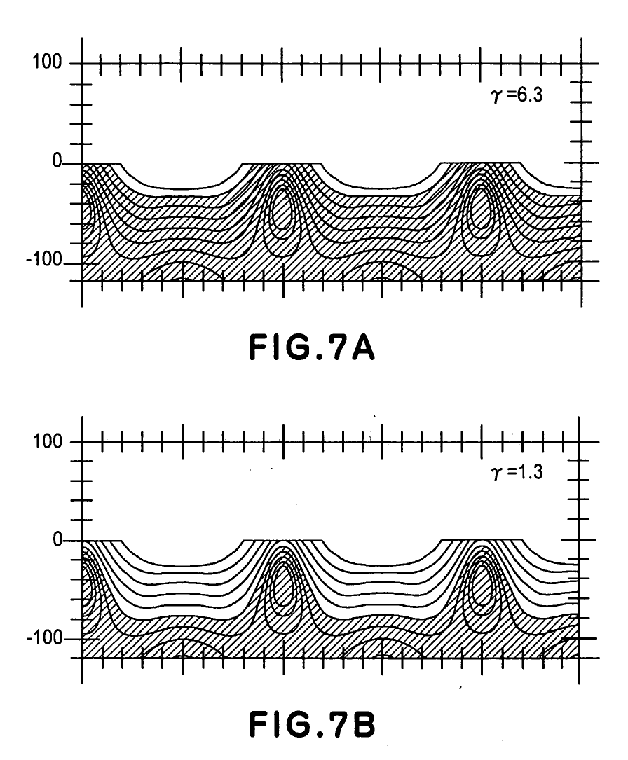

FIGS. 6 and 7 show resist latent image patterns calculated on the basis of the sensitivity curves of FIG. 4 and the light intensity distribution of FIG. 5, with the exposure amount measured upon the top of the mask being 383 mJ/cm². Specifically, FIG. 6 shows a latent image pattern of the resist B of FIG. 4. FIG. 7A shows a latent image pattern of the resist A of FIG. 4, and FIG. 7B shows a latent image pattern of the resist C of FIG. 4. Also, in FIG. 6, the gray zone size in the present invention is defined.

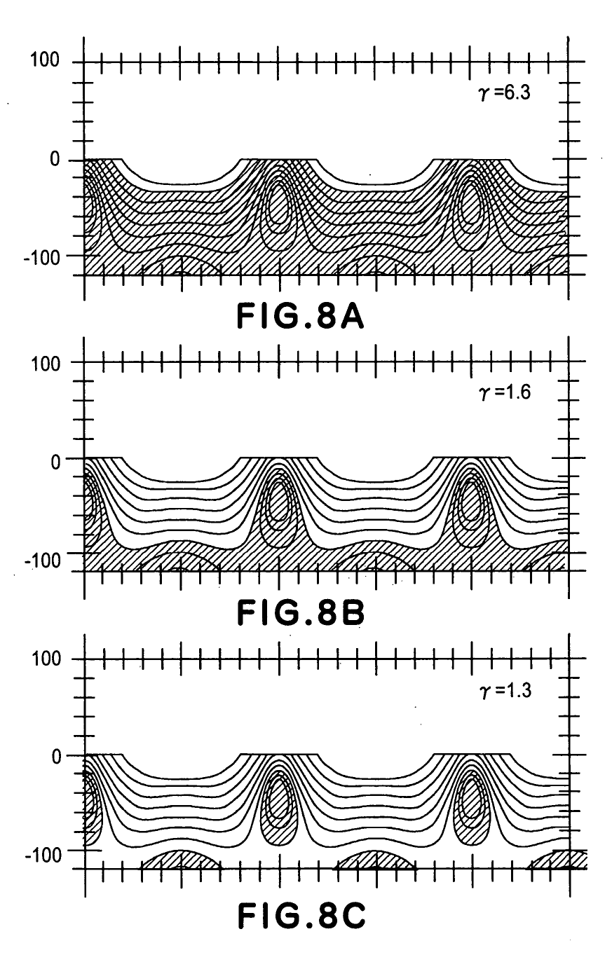

FIGS. 8A, 8B and 8C show resist latent image patterns calculated on the basis of the sensitivity curves in FIG. 4 and the light intensity distribution of FIG. 5, with the exposure amount measured upon the top of the mask being 794 mJ/cm². Specifically, FIG. 8A shows a latent image pattern of the resist A of FIG. 4, and FIG. 8B shows a latent image pattern of the resist B of FIG. 4. FIG. 8C shows a latent image pattern of the resist C of FIG. 4.

Table 1 below shows the sizes of gray zones in the latent image patterns of FIGS. 6-8C.

TABLE 1

| | | | | | | |
|---|---|---|---|---|---|---|
| Exposure Amount | 383 | 383 | 383 | 794 | 794 | 794 |
| (mJ/cm2) | | | | | | |
| Resist | A | B | C | A | B | C |
| γ Value of Resist | 6.3 | 1.6 | 1.3 | 6.3 | 1.6 | 1.3 |
| Desired Space | 113 | 113 | 113 | 156 | 156 | 156 |
| Width (top) | | | | | | |
| Gray Zone Width | 13 | 37 | 43 | 9 | 22 | — |
| (top) | | | | | | |
| Gray Zone Width | 30 | 57 | 65 | 22 | 41 | — |
| (bottom) | | | | | | |
| Gray Zone Width | 10 | 40 | 51 | 9 | 44 | — |
| (depth) | | | | | | |

Exposure Amount: Measured value on mask top surface
—: Pattern may possibly be collapsed

It is seen from Table 1 that, as a result of estimation of gray zone size by theoretical calculations, in the case of exposure amount 383 mJ/cm² and with respect to a desired space width 113 nm, the linewidth at the top of the resist after the development is in the range of 113-126 nm (resist A), 113-150 nm (resist B), and 113-156 nm (resist C). Thus, it has been found that, within the range of 1.3-6.3, a resist having a higher Y value can provide a higher resist pattern linewidth precision. Furthermore, it has been found that, for exposure amount 794 mJ/cm², in the resist C having an Y value 1.3 the pattern may possibly be collapsed.

From the results of actual measurement of the resist Y values and the results of theoretical calculations as described above, it has been confirmed that, for near-field optical lithography, use of a resist having an Y value not less than 1.6 is preferable and that, from FIG. 3, use of a resist having an Y value not less than 2.5 is particularly preferable. Thus, by forming a resist layer to be provided on a workpiece to be processed, by use of a resist material having an Y value not less than 1.6, a resist pattern having very high linewidth precision can be produced through the near-field optical lithography.

As regards a substrate to be processed which is going to be coated with such a resist having an Y value not less than 1.6, the substrate may be chosen from a wide variety of materials: examples are a semiconductor substrate such as Si, GaAs, InP, etc., an insulative substrate such as glass, quartz, BN, etc., and a substrate made of any one of these materials and having a film thereon being made of one or more of resist, metal, oxide, nitride and the like.

A resist having an Y value can be applied to a substrate by use of any known coating device and method such as spin coater, dip coater, or roller coater, for example. As regards the film thickness, it can be determined comprehensively while taking into account the processing depth of a backing substrate, plasma etching resistance of the resist material used, light intensity profile, and so on. Generally, the resist material should preferably be applied to provide a thickness of 10-300 nm after pre-baking.

Prior to coating a resist having an Y value not less than 1.6, one or more high boiling point solvents may be added to the resist in order to make the thickness after the pre-baking thinner. Examples of such solvents are benzyl ethyl ether, di-n-hexyl ether, diethylene glycol monomethyl ether, diethylene glycol monoethyl ether, acetonyl acetone, isophorone, capronic acid, caprylic acid, 1-octanol, 1-nonanol, benzyl alcohol, benzyl acetate, benzonic ethyl, diethyl oxalate, diethyl maleate, Y-butyrolacton, ethylene carbonate, propylene carbonate, and ethylene glycol monophenyl ether acetate.

The coating film of a resist having an Y value not less than 1.6 is pre-baked at a temperature of 80-200° C., more preferably, 80-150° C. The pre-baking may be done by use of heating means such as hot plate or hot air dryer, for example.

As regards the near-field optical lithography, a probe scan exposure method using a probe provided by an optical fiber having its free end sharp-pointed by wet etching or one-shot near-field exposure using a mask may be chosen. From the standpoint of throughput, use of the one-shot near field exposure method using a mask is preferable.

As regards the light source of exposure light, it may be a known light source such as, for example, carbon arc lamp, mercury vapor arc lamp, high pressure Hg lamp, xenon lamp, YAG laser, Ar ion laser, semiconductor laser, F2 excimer laser, ArF excimer laser, KrF excimer laser, visible light, etc. A single light source may be used, or plural light sources may be used in combination.

After the near-field exposure, post exposure heating (bake) may be carried out as required. It may be done at a temperature of 80-200° C., preferably, at 80-150° C. The post exposure bake can be made by using heating means such as a hot plate, a hot air dryer, etc.

A resist having an Y value not less than 1.6 can be developed by wet development using alkali aqueous solution, water-series developing agent or organic solvent, for example. The developing method may be dip method, spray method, blushing method, slapping method, etc.

On the other hand, since the propagating depth of near-field light is not greater than 100 nm, in order to produce a resist pattern of a height of 100 nm or more through the near-field optical lithography, it would be preferable to use (i) a dual-layer resist method using a structure that comprises an underlying resist layer applied onto a substrate and being able to be removed by dry etching (e.g., oxygen dry etching) and a resist layer applied onto the underlying resist layer and having oxygen dry etching resistance and an Y value not less than 1.6 (for example, a resist which contains silicon atoms), or (ii) a triple-layer resist method using a structure that comprises an underlying resist layer applied onto a substrate and being able to be removed by dry etching (e.g., oxygen dry etching), an oxygen plasma etching resistance layer made of SiO₂, for example, and a resist layer applied onto the etching resistance layer and having an Y value not less than 1.6. As regards the film thickness of the resist having an Y value not less than 1.6, in each of the dual-layer resist method and the triple-layer resist method, it should preferably be made not greater than the propagating depth of near-field light (for example, 100 nm or under).

Here, if the aspect of the resist pattern formed through the near-field exposure should be improved by the dual-layer resist method, oxygen plasma etching may be done while using the pattern as a mask. As regards an oxygen containing gas to be used for the oxygen plasma etching, usable examples are oxygen itself, a mixed gas of oxygen and an inactive gas such as argon, for example, and a mixed gas of oxygen and carbon monoxide, carbon dioxide, ammonia, dinitrogen monoxide, or sulfur dioxide, etc.

Where the dual-layer resist method such as described above is used in a resist pattern forming method, the method may preferably include (i) a resist layer forming step for forming, upon a substrate to be processed, an underlying resist layer capable of being removed by oxygen plasma etching and a resist layer having oxygen plasma etching resistance sequentially, (ii) a post exposure baking step, (iii) a developing step for performing wet development of the resist layer having oxygen plasma etching resistance by use of an alkali aqueous solution or an organic solvent, and (iv) an etching step for performing oxygen plasma etching of the underlying resist layer while using a pattern of the resist having oxygen plasma etching resistance as a mask. With this procedure, a resist pattern can be produced on the substrate.

On the other hand, if the aspect of the resist pattern formed through the near-field exposure should be improved by the triple-layer resist method, etching of the oxygen plasma etching resistance layer may be done while using the resist pattern as a mask. Although the etching may be either wet etching or dry etching, dry etching is preferable because it is more suitable to formation of a fine pattern.

As regards wet etching agent, usable examples are hydrofluoric acid aqueous solution, ammonium fluoride aqueous solution, phosphoric acid aqueous solution, acetic acid aqueous solution, nitride acid aqueous solution, cerium nitrate ammonium aqueous solution, etc., and they can be used in accordance with the object of etching.

As regards dry etching gas, usable examples are CHF₃, CF₄, C₂F₆, SF₆, CCl₄, BCl₃, Cl₂, HCl, H₂, Ar, etc. These gases may be used in combination as required.

After etching the oxygen plasma etching resistance layer in this manner, like the dual-layer resist method the oxygen plasma etching is carried out and a pattern is transferred to the underlying resist layer.

Where the triple-layer resist method such as described above is used in a resist pattern forming method, the method may preferably include (i) a resist layer forming step for forming, upon a substrate to be processed, an underlying resist layer capable of being removed by oxygen plasma etching, an oxygen plasma etching resistance layer, and the above-described resist layer sequentially, (ii) a post exposure baking step for applying heat after the exposure, (iii) a developing step for performing wet development of the resist layer by use of an alkali aqueous solution or an organic solvent, (iv) an etching step for etching the oxygen plasma etching resistance layer while using a pattern of the developed resist layer as a mask, and (v) an etching step for performing oxygen plasma etching of the underlying resist layer while using a pattern of the thus etched oxygen plasma etching resistance layer as a mask. With this procedure, a resist pattern can be produced on the substrate.

By using a substrate having a resist pattern formed thereon in accordance with the dual-layer resist method or the triple-layer resist method as described above, as a mask, one of dry etching, wet etching, metal vapor deposition, lift-off and plating may be performed, whereby the substrate can be processed.

In accordance with the substrate processing method such as described above, namely, on the basis of a substrate processing method that comprises a step of forming a resist pattern on a substrate to be processed, and a step of performing dry etching, wet etching, metal vapor deposition, lift-off or plating to the substrate having a resist pattern formed thereon, various specific devices can be produced. Examples are (1) a semiconductor device, (2) a quantum dot laser device where the method is used for production of a structure in which GaAs quantum dots of 50 nm size are arrayed two-dimensionally at 50 nm intervals, (3) a sub wavelength element (SWS) structure having antireflection function where the method is used for production of a structure in which conical SiO₂ structures of 50 nm size are arrayed two-dimensionally at 50 nm intervals on a SiO₂ substrate, (4) a photonic crystal optics device or plasmon optical device where the method is used for production of a structure in which structures of 100 nm size, made of GaN or metal, are arrayed two-dimensionally and periodically at 100 nm intervals, (5) a biosensor or a micro-total analyzer system (μTAS) based on local plasmon resonance (LPR) or surface enhancement Raman spectrum (SERS) where the method is used for production of a structure in which Au fine particles of 50 nm size are arrayed two-dimensionally upon a plastic substrate at 50 nm intervals, (6) a nano-electromechanical system (NEMS) device such as SPM probe, for example, where the method is used for production of a radical structure of 50 nm size or under, to be used in a scanning probe microscope (SPM) such as a near-field optical microscope, an atomic force microscope, and a tunnel microscope, and the like.

Briefly, these devices can be produced on the basis of a device manufacturing method, comprising the steps of: preparing an exposure mask having a pattern in accordance with device design; and forming a pattern on a substrate for device production, in accordance with a substrate processing method such as described above.

While the invention has been described with reference to the structures disclosed herein, it is not confined to the details set forth and this application is intended to cover such modifications or changes as may come within the purposes of the improvements or the scope of the following claims.

This application claims priority from Japanese Patent Application No. 2004-194821 filed Jun. 30, 2004, for which is hereby incorporated by reference.

What is claimed is:

1. A method of forming a resist pattern on a substrate to be processed, said method comprising the steps of:
forming a resist layer on the substrate;
exposing the resist layer with near-field light; and
developing the exposed resist layer;
wherein the resist layer is made of a resist material having an Y value calculated from a sensitivity curve, not less than 1.6.

2. A method according to claim 1, wherein the resist material consists of positive type or negative type chemical amplification resist having an Y value not less than 1.6, and wherein said method further comprises a post exposure baking step for applying a heat to the exposed resist after said exposing step.

3. A method according to claim 1, wherein the resist layer is formed by a resist material having an Y value calculated from the sensitivity curve, not less than 2.5.

4. A method according to claim 1, wherein the resist material has oxygen plasma etching resistance.

5. A method according to claim 4, wherein the resist material having oxygen plasma etching resistance contains silicon atoms.

6. A method according to claim 4, wherein, in said resist layer forming step, an underlying resist layer capable of being removed by oxygen plasma etching and a resist layer having oxygen plasma etching resistance are formed sequentially upon the substrate to be processed, and wherein said method includes an exposure step for performing exposure with near-field light, a post exposure baking step, a developing step for performing wet development of the resist layer having oxygen plasma etching resistance by use of an alkali aqueous solution or an organic solvent, and an etching step for performing oxygen plasma etching of the underlying resist layer while using a pattern of the resist having oxygen plasma etching resistance as a mask.

7. A method according to claim 1, wherein, in said resist layer forming step, an underlying resist layer capable of being removed by oxygen plasma etching, an oxygen plasma etching resistance layer, and the above-described resist layer are formed sequentially upon the substrate to be processed, and wherein said method includes an exposure step for performing exposure with near-field light, a post exposure baking step for applying heat after the exposure, a developing step for performing wet development of the resist layer by use of an alkali aqueous solution or an organic solvent, an etching step for etching the oxygen plasma etching resistance layer while using a pattern of the developed resist layer as a mask, and an etching step for performing oxygen plasma etching of the underlying resist layer while using a pattern of the thus etched oxygen plasma etching resistance layer as a mask.

8. A method according to claim 7, wherein the oxygen plasma etching resistance layer is made of SiO₂.

9. A substrate processing method, comprising the steps of:
forming a resist pattern on a substrate to be processed, by use of a resist pattern forming method as recited in any one of claims 1-8; and
performing one of dry etching, wet etching, metal vapor deposition, lift-off and plating to the substrate having a resist pattern formed thereon.

10. A device manufacturing method, comprising the steps of:
preparing an exposure mask having a pattern in accordance with device design; and
forming a pattern on a substrate for device production, in accordance with a substrate processing method as recited in claim 9.
